(19) United States
(12) Patent Application Publication
(10) Pub. No.: US 2014/0151632 A1
(43) Pub. Date: Jun. 5, 2014

(54) GAN-BASED VERTICAL STRUCTURE LED APPLYING GRAPHENE FILM CURRENT EXPANSION LAYER

(71) Applicants: Jinmin Li, Beijing (CN); Liancheng Wang, Beijing (CN); Yiyun Zhang, Beijing (CN); Xiaoyan Yi, Beijing (CN); Guohong Wang, Beijing (CN); Junxi Wang, Beijing (CN)

(72) Inventors: Jinmin Li, Beijing (CN); Liancheng Wang, Beijing (CN); Yiyun Zhang, Beijing (CN); Xiaoyan Yi, Beijing (CN); Guohong Wang, Beijing (CN); Junxi Wang, Beijing (CN)

(73) Assignee: INSTITUTE OF SEMICONDUCTORS, CHINESE ACADEMY OF SCIENCES, Beijing (CN)

(21) Appl. No.: 14/123,439

(22) PCT Filed: Mar. 13, 2012
(86) PCT No.: PCT/CN2012/072235

§ 371 Date: Jan. 31, 2014

(30) Foreign Application Priority Data
Jun. 2, 2011 (CN) 201110147591.1

(51) Int. Cl. H01L 33/06; H01L 33/32

(52) U.S. Cl. CPC H01L 33/06; H01L 33/32
USPC 257/13

(57) ABSTRACT

The present invention discloses A graphene film electrical current spreading layer applied GaN-based LED in vertical. structure, comprising: a p-type metal electrode including a metal support substrate and a metal reflective mirror formed on the metal support substrate; a hole injecting layer formed on the metal reflective mirror of the p-type metal electrode; an electron blocking layer formed on the hole injecting layer; a lighting layer formed on the electron blocking layer; an electron limiting layer formed on the lighting layer; an electron injecting layer formed on the electron limiting layer; an electrical current spreading layer formed on the electron injecting layer; two n-type metal electrodes formed on the electrical spreading layer and covering a part of the electrical current spreading layer.

### BACKGROUND OF THE INVENTION

1. Field of the Disclosure

The present invention pertains to semiconductor field, and particularly relates to a graphene film electrical current spreading layer applied GaN-based LED in vertical structure.

2. Description of the Related Art

In the prior art, a LED device in vertical structure is fabricated by transferring GaN epitaxial material from a sapphire substrate to a substrate material, such as, metal material, silicon, silicon carbide, etc., with high electrical and thermal conductivity by means of critical manufacturing processes, such as, thermo-compression bonding, laser stripping process, such that electrodes of the device are distributed in a vertical structure manner and electrical current is injected in a vertical direction, so as to solve a series of defects in a GaN-based LED device in a positive structure or inverse structure, including, such as, non-uniformity in heat dissipation and current distribution, poor reliability, etc, resulting from planar distributed structure of electrodes and traverse current injection. However, as metal electrodes are used in a vertical-structure LED, which is made of light-absorbing material and blocks more light as its area is increased, electrooptical conversion of this type of device is reduced. Otherwise, if light output power is increased by means of reducing area of metal electrodes, non-uniformity in current distribution and reduced contact characteristic between the electrodes and GaN material will occur, which leads to increase in contact voltage between GaN material and metal electrodes and degrade of spreading uniformity of injection current. These will seriously affect photoelectric property of GaN material LED. In addition, as precious metal material is used, cost of the device is increased.

### SUMMARY OF THE DISCLOSURE

Accordingly, it is an object of the present invention to provide a graphene film electrical current spreading layer applied GaN-based LED in vertical-structure in which the existing metal electrodes are replaced by graphene material with high light transmission and electrical, conductivity as an electrical current spreading layer, thereby increasing luminescent efficiency of LED device while reducing manufacturing cost thereof.

The present invention provides a graphene film electrical current spreading layer applied GaN-based LED in vertical-structure, comprising:

a p-type metal electrode including a metal support substrate and a metal reflective mirror formed on the metal support substrate;

a hole injecting layer formed on the metal reflective mirror of the p-type metal electrode;

an electron blocking layer formed on the hole injecting layer;

a lighting layer formed on the electron blocking layer;

an electron limiting layer formed on the lighting layer;

an electron injecting layer formed on the electron limiting layer;

an electrical current spreading layer formed on the electron injecting layer;

two n-type metal electrodes formed on the electrical spreading layer and covering a part of the electrical current spreading layer.

The material of the metal support substrate of the p-type metal electrode is selected from the group consisting of: copper, nickel, copper-nickel alloy, copper-tungsten alloy and nickel-cobalt alloy.

The material of the metal reflective mirror of the p-type metal electrode is selected from the group consisting of: nickel/silver/platinum/gold multiple layers structure, nickel/silver/gold multiple layers structure, nickel/silver/nickel/gold multiple layers structure, titanium/aluminium/titanium/gold multiple layers structure, titanium/silver/titanium/gold multiple layers structure, aluminium/silver/gold multiple layers structure and aluminium/titanium/gold multiple layers structure.

The hole injecting layer is made from p-type GaN material doped by magnesium.

The electron blocking layer is made of material selected from AlₓGa₁₋ₓN, in which x is in the range of 0≦x≦1.

The lighting layer includes m InGaN quantum well and m+1 GaN quantum barrier, each InGaN quantum well being respectively associated with a GaN quantum barrier at its upper and lower sides thereof, wherein in is no less than 1.

The electron limiting layer is made of material selected from Al_{z}Ga_{1-z}N with z in the range of 0≦z≦1.

The electron injecting layer is made of n-type GaN material doped by silicon.

The electrical current spreading layer is made of single or multiple layer grapheme film material.

The n-type metal electrodes are made of material selected from the group consisting of: nickel/gold multiple layers structure, nickel/silver/gold multiple layers structure, nickel/silver/nickel/gold multiple layers structure, nickel/silver/platinum/gold multiple layers structure, titanium/gold multiple layers structure, titanium/silver/gold multiple layers structure, titanium/aluminium/titanium/gold multiple layers structure, titanium/silver/titanium/gold multiple layers structure, aluminium/titanium/gold multiple layers structure, chromium/platinum/gold multiple layers structure and chromium/silver/gold multiple layers structure.

### BRIEF DESCRIPTION OF THE DRAWINGS

A more complete understanding of the structure, features and objectives of the present invention may be had by studying the following description of the preferred embodiment and by referring to the accompanying drawings, in which:

FIG. 1 is a schematic side view of the LED in vertical structure;

FIG. 2 is a schematic perspective view of the LED in vertical structure.

### DETAILED DESCRIPTION OF THE PREFERRED EMBODIMENT

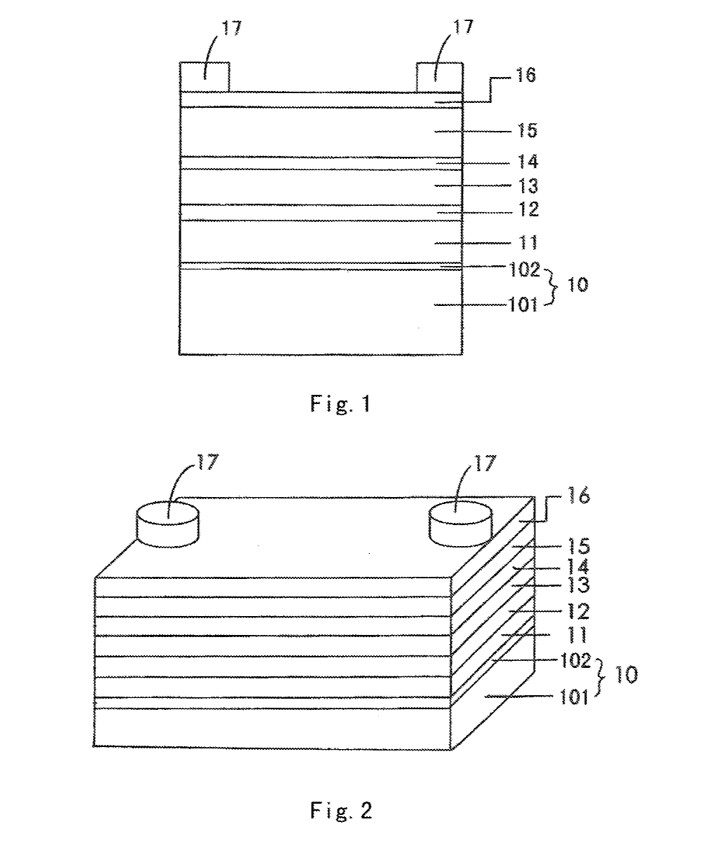

An embodiment of the present invention is described as below in detailed with reference to the FIGS. 1 and 2.

As shown in FIGS. 1, 2, a graphene film electrical current spreading layer applied GaN-based LED in vertical-structure is provided, comprising:

a p-type metal electrode 10, which includes a metal support substrate 101 and a metal reflective mirror 102 formed on the metal support substrate 101. The metal support substrate 101 functions to support epitaxial material and dissipate heat from device. The metal reflective mirror 102 is provided to firmly bond GaN material to the metal support substrate 101 and, due to its good reflectivity and electrical conductivity, promote uniformly lighting and thus strongly improve light extracting efficiency of the device. The material of the metal support substrate 101 of the p-type metal electrode 10 is selected from the group consisting of: copper, nickel, copper-nickel alloy, copper-tungsten alloy and nickel-cobalt alloy, and the thickness thereof is in the range from 50 μm to 300 μm. The material of the metal reflective mirror 102 of the p-type metal electrode 10 is selected from the group consisting of: nickel/silver/platinum/gold multiple layers structure, nickel/silver/gold multiple layers structure, nickel/silver/nickel/gold multiple layers structure, titanium/aluminium/titanium/gold multiple layers structure, titanium/silver/titanium/gold multiple layers structure, aluminium/silver/gold multiple layers structure and aluminium/titanium/gold multiple layers structure, and the thickness thereof is in the range from 100 μm to 2 μm;

a hole injecting layer 11 formed on the metal reflective mirror 102 of the p-type metal electrode 10, which hole injecting layer 11 is made from p-type GaN material doped by magnesium and has a thickness from 100 nm to 500 nm;

an electron blocking layer 12 formed on the hole injecting layer 11, which is configured to define electron within the lighting region so as to reduce non-recombination probability due to electron leakage, and thus increase quantum efficiency within the device, the electron blocking layer 12 being made of material selected from AlₓGa₁₋ₓN with x in the range of 0≦x≦1 and having a thickness from 50 nm to 50 nm;

a lighting layer 13 formed on the electron blocking layer 12, which includes m InGaN quantum well and m+1 GaN quantum barrier, each InGaN quantum well being associated with a GaN quantum barrier at either side thereof, wherein m is no less than 1;

an electron limiting layer 14 formed on the lighting layer 13, which functions to decelerate electron migrating in high speed and thus reduces probability of electron entering the hole injecting layer 11 through the lighting layer 13, thereby increasing radiation recombination probability of carriers in the lighting region and enhancing injecting efficiency of carriers, the electron limiting layer 14 being made of material selected from Al_{z}Ga_{1-z}N with z in the range of 0≦z≦1;

an electron injecting layer 15 formed on the electron limiting layer 14, which is made of n-type GaN material doped by silicon and has a thickness from 1 μm to 5 μm;

an electrical current spreading layer 16 formed on the electron injecting layer 15, which promotes electrical current injected to be evenly spread on the electron injecting. layer 15 by means of grapheme material with high electrical conductivity and light transmission, thereby increasing lighting efficiency of the device, the electrical current spreading layer 16 being made of single or multiple layer grapheme film material;

two n-type metal electrodes 17 formed on the electrical spreading layer 16, which are made of material selected from the group consisting of: nickel/gold multiple layers structure, nickel/silver/gold multiple layers structure, nickel/silver/nickel/gold multiple layers structure, nickel/silver/platinum/gold multiple layers structure, titanium/gold multiple layers structure, titanium/silver/gold multiple layers structure, titanium/aluminium/titanium/gold multiple layers structure, titanium/silver/titanium/gold multiple layers structure, aluminium/titanium/gold multiple layers structure, chromium/platinum/gold multiple layers structure and chromium/silver/gold structure, and both cover a part of the electrical current spreading layer 16.

### EXAMPLE

With reference to FIGS. 1 and 2, it is provided a graphene film electrical current spreading layer applied GaN-based LED in vertical structure, comprising:

a p-type metal electrode 10, which includes a copper support substrate 101 with a thickness of 100 μm and a metal reflective mirror 102 including nickel/silver/platinum/gold multiple layers structure formed on the copper support substrate 101, wherein the multiple layers structure of nickel/silver/platinum/gold is configured as 0.5 nm/50 nm/50 nm/400 nm in multiple layers structure for thickness of respective layer;

a hole injecting layer 11 made from p-type GaN material with a thickness of 100 nm;

an electron blocking layer 12 made of Al_{0.2}Ga_{0.8}N material with a thickness of 20 nm, which is formed on the hole injecting layer 11;

a lighting layer 13 with a thickness of 100 nm formed on the electron blocking layer 12, which includes 5 InGaN quantum well and 6 GaN quantum barrier, each InGaN quantum well being respectively associated with a GaN quantum barrier at upper and lower side thereof;

an electron limiting layer 14 made of Al_{0.15}Ga_{0.85}N material with a thickness of 10 nm, which is formed on the lighting layer 13;

an electron injecting layer 15 made of n-type GaN material doped by silicon with a thickness of 2 μm, which is formed on the electron limiting layer 14;

an electrical current spreading layer 16 made of single or multiple layer grapheme film material, which is formed on the electron injecting layer 15;

two n-type metal electrodes 17 having a multiple layers structure of titanium/aluminium/titanium/gold multiple layers structure with 0.5 μm/50 μm/50 μm/1.5 μm for respective layer, which is formed on the electrical spreading layer 16.

The above embodiments are only illustrative and should not be construed as limiting on scope of the invention. It should be appreciated that the modification or alternative form of embodiments can be realized in light of the disclosed embodiments and shall fall into the scope of the present invention. The protective scope of the present invention is determined by the appended claims.

1. A graphene film electrical current spreading layer applied GaN-based LED in vertical structure, comprising:
a p-type metal electrode including a metal support substrate and a metal reflective mirror formed on the metal support substrate;
a hole injecting layer formed on the metal reflective mirror of the p-type metal electrode;
an electron blocking layer formed on the hole injecting layer;
a lighting layer formed on the electron blocking layer;
an electron limiting layer formed on the lighting layer;
an electron injecting layer formed on the electron limiting layer;
an electrical current spreading layer formed on the electron injecting layer;
two n-type metal electrodes formed on the electrical spreading layer and covering a part of the electrical current spreading layer.

2. The graphene film electrical current spreading layer applied GaN-based LED in vertical structure according to claim 1, characterized in that,
the material of the metal support substrate of the p-type metal electrode is selected from the group consisting of: copper, nickel, copper-nickel alloy, copper-tungsten alloy and nickel-cobalt alloy.

3. The graphene film electrical current spreading layer applied GaN-based LED in vertical structure according to claim 1, characterized in that,
the material of the metal reflective mirror of the p-type metal electrode is selected from the group consisting of nickel/silver/platinum/gold multiple layers structure, nickel/silver/gold multiple layers structure, nickel/silver/nickel/gold multiple layers structure, titanium/aluminium/titanium/gold multiple layers structure, titanium/silver/titanium/gold multiple layers structure, aluminium/silver/gold multiple layers structure and aluminium/titanium/gold multiple layers structure.

4. The graphene film electrical current spreading layer applied GaN-based LED in vertical structure according to claim 1, characterized in that,
the hole injecting layer is made from p-type GaN material doped by magnesium.

5. The graphene film electrical current spreading layer applied GaN-based LED in vertical structure according to claim 1, characterized in that, the electron blocking layer is made of material selected from AlₓGa₁₋ₓN, in which x is in the range of 0≦x≦1.

6. The graphene film electrical current spreading layer applied GaN-based LED in vertical structure according to claim 1, characterized in that,
the lighting layer includes m InGaN quantum well and m+1 GaN quantum barrier, each InGaN quantum well being respectively associated with a GaN quantum barrier at its upper and lower sides thereof, wherein m is no less than 1.

7. The graphene film electrical current spreading layer applied GaN-based LED in vertical structure according to claim 1, characterized in that,
the electron limiting layer is made of material selected from Al_{z}Ga_{1-z}N with z in the range of 0≦z≦1.

8. The graphene film electrical current spreading layer applied GaN-based LED in vertical structure according to claim 1, characterized in that,
the electron injecting layer is made of n-type GaN material doped by silicon.

9. The graphene film electrical current spreading layer applied GaN-based LED in vertical structure according to claim 1, characterized in that,
the electrical current spreading layer is made of single or multiple layer grapheme film material.

10. The graphene film electrical current spreading layer applied GaN-based LED in vertical structure according to claim 1, characterized in that,
the n-type metal electrodes are made of material selected from the group consisting of nickel/gold multiple layers structure, nickel/silver/gold multiple layers structure, nickel/silver/nickel/gold multiple layers structure, nickel/silver/platinum/gold multiple layers structure, titanium/gold multiple layers structure, titanium/silver/gold multiple layers structure, titanium/aluminium/titanium/gold multiple layers structure, titanium/silver/titanium/gold multiple layers structure, aluminium/titanium/gold multiple layers structure, chromium/platinum/gold structure and chromium/silver/gold structure.
